(19) United States
(12) Patent Application Publication
(10) Pub. No.: US 2018/0124913 A1
(43) Pub. Date: May 3, 2018

(54) RF INTERCONNECT

(71) Applicant: Innovative Micro Technology, Goleta, CA (US)

(72) Inventor: Christopher S. GUDEMAN, Lompoc, CA (US)

(73) Assignee: Innovative Micro Technology, Goleta, CA (US)

(21) Appl. No.: 15/800,130

(22) Filed: Nov. 1, 2017

Related U.S. Application Data
(60) Provisional application No. 62/416,757, filed on Nov. 3, 2016.

(51) Int. Cl. H05K 1/02; H05K 3/42; H05K 1/03; H05K 3/46; H05K 1/11; H05K 1/09; H01P 3/00; H05K 1/18

(52) U.S. Cl. CPC H05K 1/0237; H05K 3/421; H05K 1/0216; H05K 1/0353; H05K 3/46; H05K 2203/041; H05K 1/0298; H05K 1/09; H01P 3/003; H05K 1/18; H05K 1/115

(57) ABSTRACT

We describe below a structure and process that uses through-silicon-vias and wafer-to-wafer bonding to create transmission lines. The method may require one electroplating step, 3 etch steps, 4 lithography steps, one grind and polish step, and one wafer bonding step, totaling ten process steps per transmission line layer.

### CROSS REFERENCE TO RELATED APPLICATIONS

This U.S. Patent Application claims priority to U.S. Provisional Application Ser. No. 62/416757, filed Nov. 3, 2016 and incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

This invention relates to a system for providing electrical signals to signal processing components.

In complex radio circuits, it is generally necessary to route high frequency (1 MHz-40 GHz) signals to and from multiple components, such as amplifiers, filters, mixers, and detectors. Compact RF circuit designs dictate that the electrical traces and/or wires be routed in close proximity and over the top of one other. Inductive coupling between these traces increases with increasing frequency, thus forcing the routing paths to detour to avoid one another, or alternatively forcing the use of bulky shielding sheaths covering each trace, which makes compact design unachievable. The prior art includes:

1) Printed Circuit Boards. The minimum electrical line spacing and width is limited to ˜100 μm by the materials and processes used to fabricate these boards.

2) Coaxial cable. Again fabrication processes limit the smallest diameters to ˜300 μm. Also, these cables need to be connectorized for implementation in a complex circuits, thus adding complexity, size, and cost.

3) Multilayer Air-Coax. Here a coaxial transmission lines created by electroplating layer by layer 250 μm coaxial structures, where the center conductor is released from the outer shield by etching away a sacrificial material. Although these structures provide for a compact routing of high frequency signals, the process to make even just two routing layers requires 25-30 lithographic masking layers, each of which is followed by a plating and planarization, totaling ˜29 process steps per transmission line layer. This is a very costly and time consuming process.

Accordingly, there exists an unmet need to a cost-effective, small scale, low loss, low cost RF signal handling system for small RF devices.

### SUMMARY

Described here is a structure and manufacturing process to that overcomes these problems, to render an inexpensive transmission line for RF structures.

This structure and process uses through-silicon-vias and wafer-to-wafer bonding to create transmission lines. Each transmission line layer consist of one electroplating step, 3 etch steps, 4 lithography steps, one grind and polish step, and one wafer bonding step, totaling ten process steps per transmission line layer. Similar dimensions to the prior art can be achieved with this technology. Furthermore, devices such as amplifiers, filters, mixers, for example, may be embedded within the stack of complex routing layers, thus permitting additional reduction of the overall part size.

Accordingly, a method is described for forming a transmission line using seminconductor wafers. The method may include forming at least one signal via and one ground via though a first substrate, forming a shield layer over the substrate which is configured to block RF radiation, and coupling the ground via to the shield layer.

An interconnect for an RF signal handling device may be formed using this method. The interconnect may include at least one signal via and one ground via formed though a first substrate, a shield layer formed over the first substrate wherein the shield layer is configured to block RF radiation, wherein the ground via is electrically coupled to the shield layer.

### BRIEF DESCRIPTION OF THE DRAWINGS

Various exemplary details are described with reference to the following figures, wherein:

FIG. 1a is a cross sectional diagram of an embodiment of an RF interconnect through the first fabrication step; FIG. 1b is a cross sectional diagram of an embodiment of an RF interconnect through the second fabrication step;

FIG. 2a is a cross sectional diagram of an embodiment of an RF interconnect after a grinding step; FIG. 2b is a cross sectional diagram of an embodiment of an RF interconnect with a third substrate added; FIG. 2c is a cross sectional diagram of an embodiment of an RF interconnect with a fourth substrate added; and FIG. 2d is a cross sectional diagram of an embodiment of an RF interconnect with a fourth substrate ground back to reveal the TSVs;

FIG. 3 is a cross sectional diagram of an embodiment of an RF interconnect in its final form;

FIG. 4a is a cross sectional diagram of an embodiment of an RF interconnect through the third fabrication step before bonding the wafer pair; FIG. 4b is a plan view of an embodiment of an RF interconnect through the fourth fabrication step before bonding the wafer pair; and

FIG. 5a is a cross sectional diagram of an embodiment of an RF interconnect through the third fabrication step after bonding the wafer pair; FIG. 5b is a plan view of an embodiment of an RF interconnect through the fourth fabrication step after bonding the wafer pair.

It should be understood that the drawings are not necessarily to scale, and that like numbers may refer to like features.

### DETAILED DESCRIPTION

We describe below a structure and process that uses through-silicon-vias (TSV) and wafer-to-wafer bonding to create transmission lines. Each transmission line layer consists of one electroplating step, 3 etch steps, 4 lithography steps, one grind and polish step, and one wafer bonding step, totaling ten process steps per transmission line layer. Similar dimensions to the prior art can be achieved with this technology, but at a fraction of the cost. Furthermore, the method allows devices such as amplifiers, filters, mixers, etc. to be embedded within the stack of complex routing layers, thus permitting additional reduction of the overall part size.

It should be understood that throughout this description, the terms “wafer” and “substrate” are used interchangeably to refer to a generally flat, circular, often semiconductor material that is used to fabricated small devices using lithographic methods. The term “transmission line” refers to a structure having a plurality of conductors configured to transmit an AC signal with low loss. A transmission line may be impedance matched in addition, such that a signal may be injected into the structure and transmitted to an end point with low loss. The term “interconnect” may refer to a multilayer structure, wherein one layer is connected, either electrically or mechanically or both, to at least one adjacent layer. As used herein, an interconnect may also be configured to be a low loss transmission line. A co-planar waveguide should be understood to mean a transmission line using parallel conductors deposited on adjacent planes.

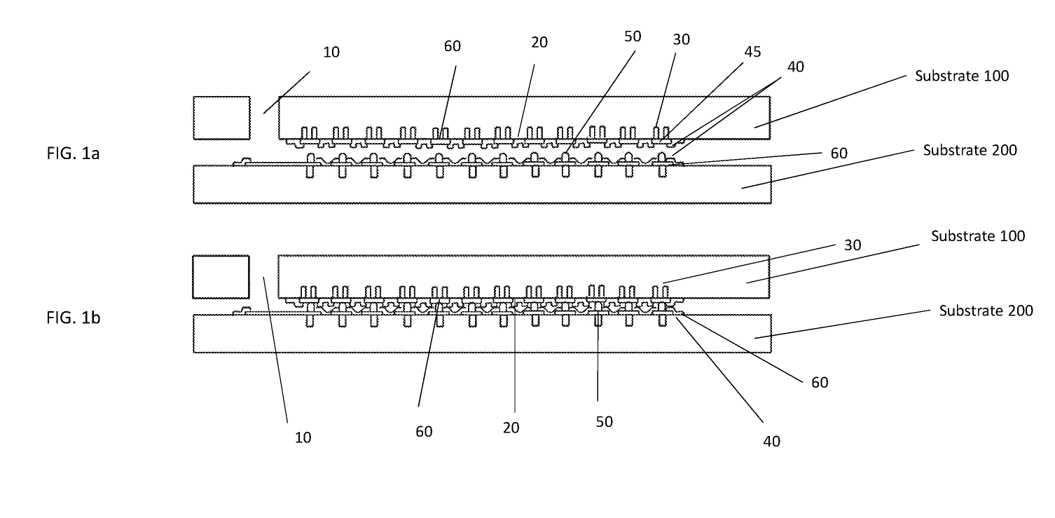

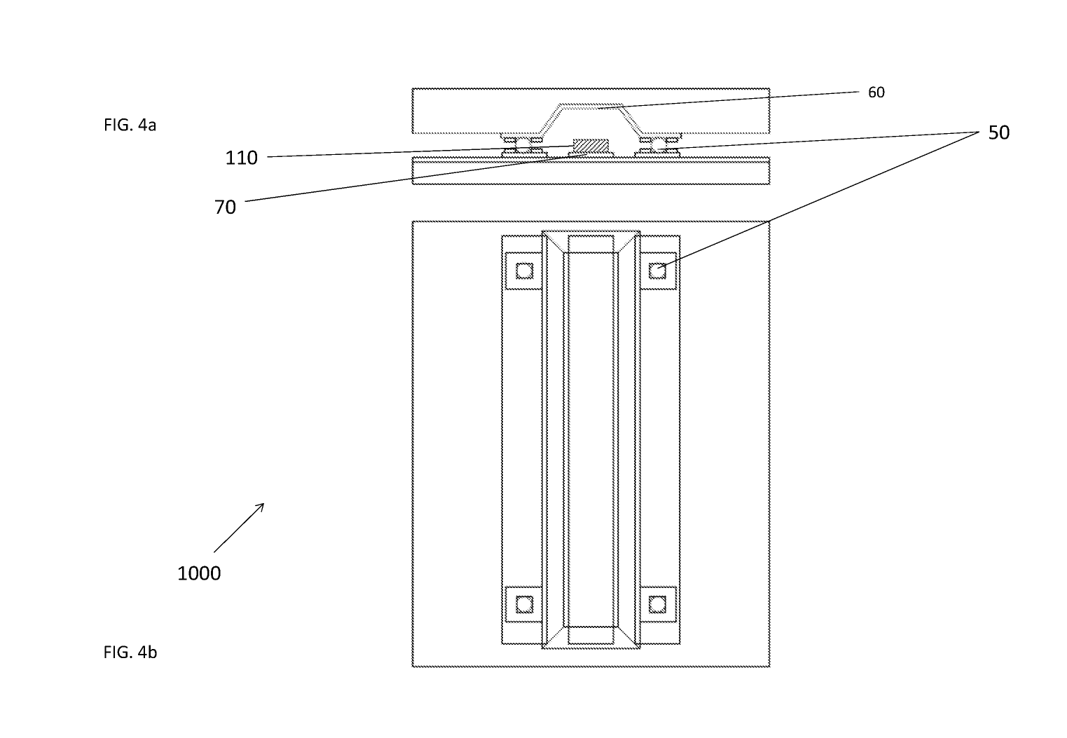

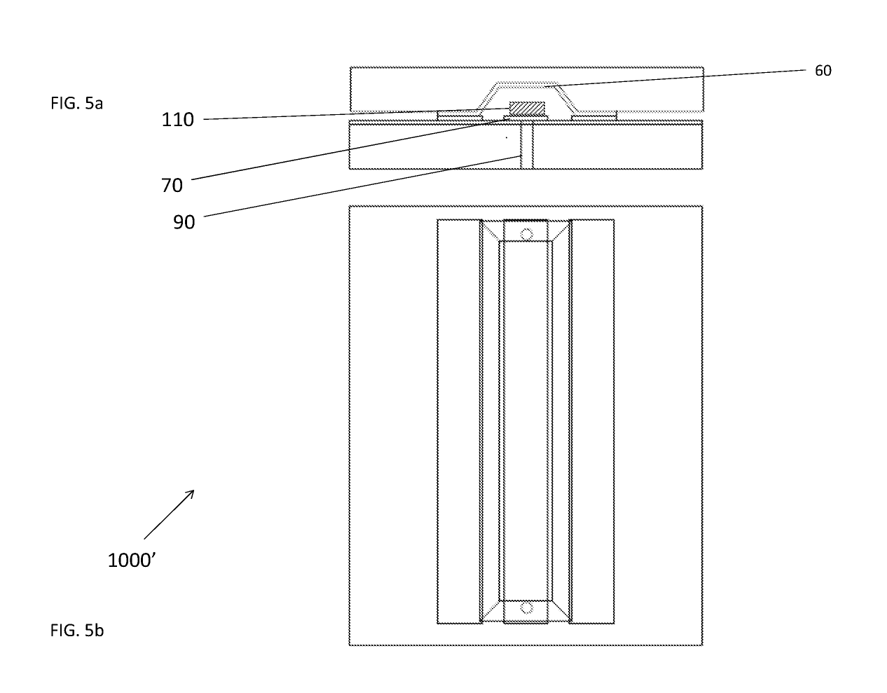

The various embodiments are shown in FIGS. 1, 2 and 3 attached. FIGS. 4 and 5 show the bonding method which forms the transmission line/interconnect/co-planar waveguide. In FIGS. 1-5, like numbers refer to like features. Accordingly,

10 access hole

20 dielectric layer

30, 32, 34, 36, 38 TSVs

40 solder dam

45 solder mask

50 solder ball

60 unpatterned metal layer (shield)

70 patterned metal layer (signal traces)

100 first substrate

110 semiconductor chip

200 second substrate

300 third substrate

400 fourth substrate

1000, 1000′ transmission lines

These features may be fabricated as follows, and asdepicted in FIGS. 1, 2 and 3. For the first wafer 100, the TSV holes 30-38 may be etched in the substrate, using for example, deep reactive ion etching (DRIE). The walls of the holes and other surfaces may then be provided with an insulating layer, for example a thermal oxide. Methods for forming silicon dioxide for example, are well known in the art, and often include baking the wafer in an oven with a humid atmosphere at between about 800 and 1200 degrees centigrade.

A seed layer may then be deposited in the TSV holes. The seed layer may be, for example, a conformal layer of copper deposited on the insulating walls by, for example, sputter deposition. The seed layer may then be connected to an electrode in the plating bath so as to plate the species, for example, copper (Cu) into the TSV holes.

Deposition by plating can result in the deposition of the plated material proud with respect to the surrounding substrate. This excess material can be removed and the surface planarized by chemical mechanical planarization (CMP), a process well known in the art.

Electrical access to the copper TSVs may be accomplished by depositing a metal pad over the copper TSVs. In one embodiment, the metal pad may be gold (Au). Electrical traces may provide access to the pad and TSV. These TSVs 30 may deliver signal 34, 38 or ground 32, 36. This process may be referred to generally herein as an electroplating step.

The metal pads and traces may optionally be a multilayer stack, and may include an adhesion layer and a diffusion barrier layer. Such multilayers, rather than a single layer of metal material may be advantageous to promote adhesion. For example, if the pad is a gold layer, it may also include a thin layer of chromium (Cr) which promotes adhesion of the gold layers and to the surface of the substrate. The chromium layer may be, for example, about 50 Angstroms to about 200 Angstroms in thickness. Furthermore, there may also be diffusion barrier layers present, to prevent the diffusion of the metal of the adhesion layer into metal layer or metal layer.

For example, the gold layers and may also include a thin layer of molybdenum, about 100 Angstroms in thickness, which prevents the diffusion of the chromium adhesion layer into the gold layer, which would otherwise increase the electrical resistance of the metal layer. The remainder of metal layer may be gold, which may be, for example, 3000 Angstroms to about 5000 Angstroms in thickness. The pads and traces may be patterned by etching a contiguous layer through a mask, or depositing the material only in certain exposed areas.

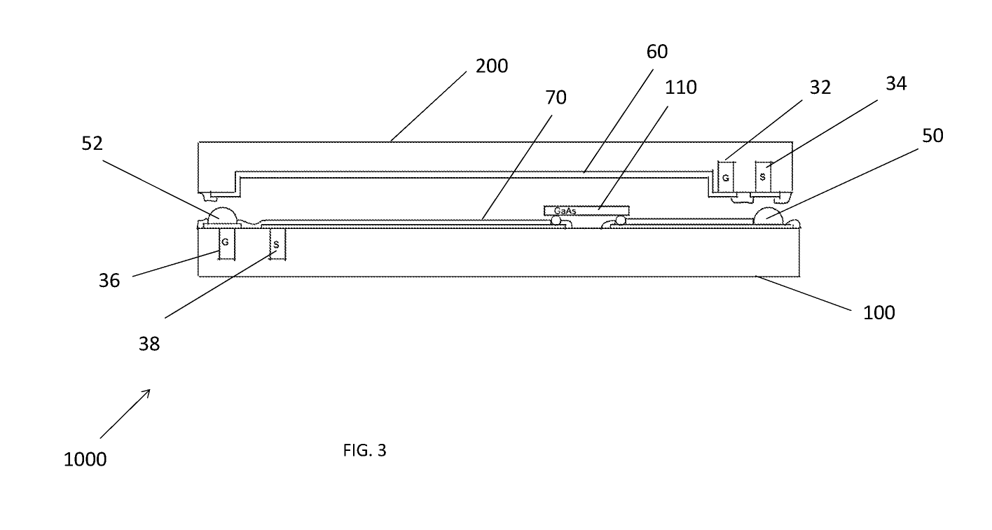

The gold layer may be patterned to form the metal traces 70 leading to and from a device 110. These traces 70 may be formed photolithographically, and the process may be referred to generally herein as an lithography step. These traces 70 may also be referred to as signal lines, and are generally electrically coupled to a signal via such as signal via 34 and 38 in FIG. 3.

Alternatively, the layer may be unpatterned, generally contiguous, and thereby be configured as a shield layer 60 that provides the shielding for the transmission line/co-planar waveguide 1000. The shield layer may be configured to block RF radiation traveling to or from the device 110. The shield layer may be a metallic shield layer, and may cover a majority of an inner surface of a device cavity which encloses a device between two substrates. These unpatterned layer 60 may also be referred to as a shield, and are generally electrically coupled to a ground via such as signal via 32 and 36 in FIG. 3.

A solder material may then be applied to the wafer surface though, for example, a screen or deposited through a mask. The material may be a wetting agent that will attract molten solder to certain areas, such as the pads and traces. The solder mask 45 may be a solder wetting agent, with an affinity for the molten solder material from solder balls 50.

Upon completion of these processing steps, a similar or identical second wafer 200 may be fabricated and bonded to wafer 100.

Accordingly, wafer 200 may be handled in a similar or identical way to wafer 100. Wafer 200 may be etched to form TSVs, then oxidized, then seed layer deposited, then plated with a conductive species, for example copper. The surface of wafer 200 may then be planarized using CMP for example, and pads and traces deposited and patterned as with wafer 100 and described above. After deposition of the solder agent, solder material may be placed by deposition, or solder balls may be applied by a pick and place machine. The condition of wafer 100 and wafer 200 is depicted in FIG. 1a.

FIG. 1a shows the first substrate 100 held aloft of the second substrate 200. In FIG. 1a, 10 represents a thru wafer etch that permits access to electrical pads that are sandwiched between the two wafers. 20 refers to a dielectric passivation layer that may also act as a solder dam. 40 represents the solder dam on the opposing wafer and 50 refers to a solder ball that will form the bond between the two wafers. This solder ball can be SAC405, SAC305, AuSn, PbSn, or other soldering materials known by one skilled in the art. 70 represent the metal traces of the transmission lines, as well as the pads that are alloyed during the solder bonding process. The features. 30-38 are through Si vias that will layer be exposed by thinning The first wafer 100 and the second wafer 200 are then aligned and brought together, such that solder balls 50 rest between the solder dams 40, as shown in FIG. 1b.

After wafers 100, 200 are mated to form a wafer pair, the wafers are separated by the diameter of the solder balls. The bonding process may proceed by melting the solder balls under temperature and with some pressure applied between the wafers. When the solder melts, it flows into the areas wherein the solder wetting agent has been applied as described above.

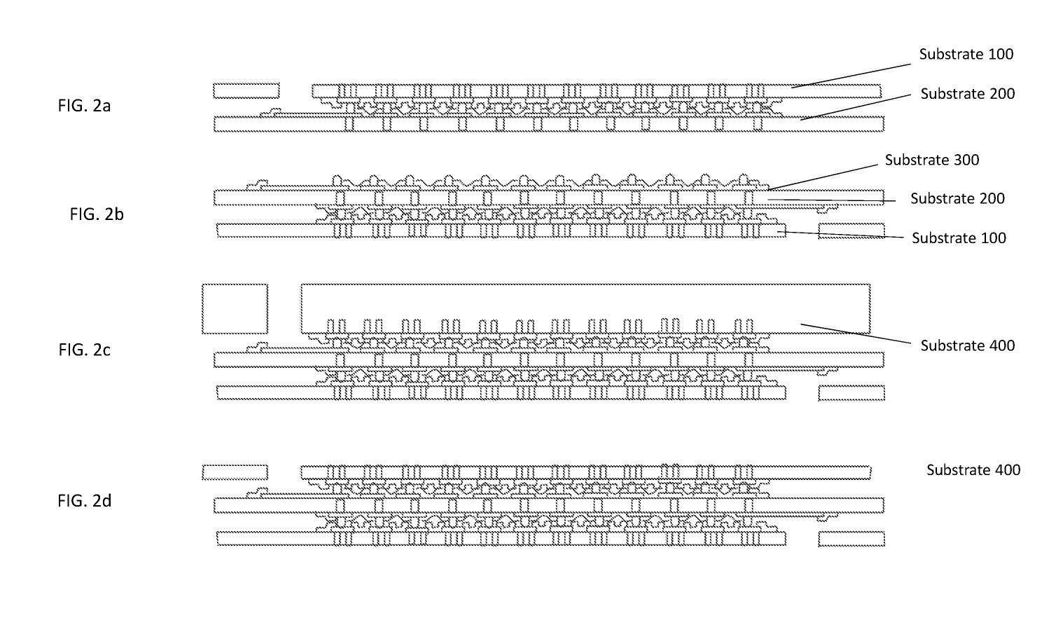

After bonding, the substrate material in first substrate 100 and second substrate 200 is ground back to reveal the TSVs formed therein as blind, metal filled holes. The situation is shown in FIG. 2a, after both the first wafer 100 and the second wafer 200 are ground back to reveal the TSVs 30.

The wafer pair may then be placed in an oven and pressure applied between the first wafer 100 and the second wafer 200. As the solder balls 50 melts, the wafers 100 and 200 approach one another and are adhered by the freezing solder 50. The solder may also form a conductive path between the first wafer 100 and the second wafer 200. This conductive path may join the signal lines on the first wafer and the second wafer and the ground lines on the first wafer 100 and the second wafer 200. As solder ball 50 melts, it wets the metals trace 60 and flows out to the solder dam 40. Upon refreezing, the solder material adheres the first wafer 100 to the second wafer 200.

At this point in fabrication, the remainder of the substrate material 100 and substrate material 200 covers the through substrate vias 30, until this material is removed by grinding the backside material in step 2, as described below and illustrated in FIGS. 2a, 2b. The backside of wafer 100 may be ground and polished to a desired thickness. The backside may then have metallization applied to provide electrical access to the TSVs which were formed in wafer 100. Similarly, the backside of wafer 200 may be ground and polished to a desired thickness. The backside of wafer 200 may then have metallization applied to provide electrical access to the TSVs which were formed in wafer 2.

This bonded pair then becomes a substrate for further stacking, thus creating more transmission lines as described further below.

The description now turns to the formation of a multi-substrate transmission line structure from a wafer 100 and wafer 200 as described above.

Additional substrates may be formed as described above for wafer 100 and wafer 200. For example, a third substrate 300 may be fabricated with the features described above for wafers 100 and 200. The third substrate 300 may be aligned and bonded as described above and shown in FIG. 2b. The condition of the wafer 100, 200 and 300 is shown in FIG. 2b

FIG. 2c shows a fourth substrate 400 coupled to the substrate assembly 100, 200 and 300. The fourth substrate 400 may be fabricated as described above with respect to substrates 100 and 200. As before, solder balls 50 placed between solder dams 40 may provide the adhesive material that bonds the wafers together. Fourth wafer 400 may also have an access hole 10 formed therein, which allows electrical access to the interior of the transmission line.

FIG. 2d shows the fourth wafer 400, after grinding down to reveal the TSVs 30 fabricated in the fourth wafer 400. This back grinding may be done as described above, by mechanical grinding or chemical etching, for example.

FIG. 3 shows how this same process and architecture can be used to form an impedance controlled transmission line, with an embedded chip 110. FIG. 3 is a cross sectional diagram of an embodiment of an RF interconnect in its final form, wherein device 110 represents a semiconductor chip, which is embedded in the cavity formed between the two wafers 100 and 200. The embedded chip 110 may be fabricated using standard lithographic or thin film processing techniques as is well known in the art. The semiconductor device 110 may be an integrated circuit (IC) or a microelectromechanical systems (MEMS) device, for example. The device 110 may be fabricated separately and disposed on wafer 200 by a pick and place machine. It may alternatively be fabricated directly on the first wafer 100. In any case, the device 110 may include leads that allow a signal to be input to or carried from the device 110.

These leads may be fabricated by patterning traces in a conductive layer, such as patterned conductive layer 70, described earlier. The traces or leads may carry an RF signal to or from the semiconductor device 110. On the opposing surface of the second wafer 200 may be a generally unpatterned, contiguous conductive layer 60 which may be grounded to the ground terminal of the semiconductor device 110 as described with respect to FIG. 1b. In particular, the ground layer 60 may be coupled electrically to ground line on the opposing wafer by one of the solder balls 52. Accordingly, layer 60 may function as a shield layer in the transmission line, and may be disposed adjacent the signal lines in the patterned conduction layer 70. The other solder ball may coupled electrically the signal lines. The shield layer may be a metallic shield layer, and may cover a majority of an inner surface of a device cavity which encloses a device between substrates 100 and 200.

FIG. 4a is a schematic cross sectional diagram of the structure 1000 including the wafer pair 100, 200 with enclosed device 110 before bonding. FIG. 4a shows the positioning of at least one solder ball 50 between the solder dams 40 and on top of metal layer 60. FIG. 4a also shows the device cavity that may enclose the device 110. The device may be enclosed hermetically, or the device cavity 80 may be formed simply by bonding the first wafer 100 to the second wafer 200. In either case, the solder balls 50 may form the adhesive material which bonds the wafers.

FIG. 4b is a plan view of the structure showing the device 110 enclosed in the device cavity 80. The solder balls 50 are shown placed at the four corners of the device cavity 80. By providing the electrical connection between the signal lines 70 and the ground lines 60, the multi-wafer structure 1000 may form a low loss, impedance matched transmission line for conducting the RF signal to or from the device 110.

FIG. 5a shows the same structure 1000′after bonding the first wafer 100 to the second wafer 200. FIG. 5a shows also another through substrate via 90 formed in the first wafer 100. This TSV 90 may provide access to the enclosed device 110 from the outside world. After bonding, the solder ball material 50 may couple electrically the signal line on the first wafer 100 to the signal line on the second wafer 200. The two wafers 100 and 200 may thereby form a co-planar waveguide which may transmit an RF signal with low loss. This co-planar waveguide is relatively easy to fabricate, robust, inexpensive and straightforward to implement in a thin film lithographic manufacturing environment. The bonding mechanism in FIG. 4a, 4b may solder ball bonding, wherein solder material is melted from the solder ball and flows onto the solder mask patterned as described above. This bonding mechanism may not necessarily be hermetic, but may be relatively cheap and easy in terms of cost of materials, precision of alignment and complexity of process.

FIG. 5b shows the plan view of the structure 1000′ after bonding the first wafer 100 to the second wafer 200. FIG. 5b also shows also through substrate via 90 formed in the first wafer 100, which may provide access to the enclosed device 110 from the outside world. After bonding, the solder ball material 50 may couple electrically the signal line on the first wafer 100 to the signal line on the second wafer 200, to form the co-planar.

The bonding material in the embodiment 1000′ may be gold, such that the bondline may be a gold-gold thermocompression bond. Such a noble metal thermocompression bond may be hermetic or substantially hermetic, which may be important for devices which need to be protected from environmental factors for robust, long-term reliability.

More generally, the process may include:

one electroplating step;

at least one etch step;

at least one lithography steps;

one grind step;

one polish step; and

one wafer bonding step. and the process may include a total of 10 or fewer steps.

Accordingly, disclosed here is a method for forming a transmission line using wafers or substrates. The method may include forming at least one signal via and one ground via though a first substrate, forming a shield layer over the substrate which is configured to block RF radiation, and coupling the ground via to the shield layer. The shield layer may comprise at least one of gold (Au), silver (Ag) copper (Cu) or aluminum (Al), and the substrate is a semiconductor substrate comprising at least one of silicon, germanium, gallium arsenide, gallium phosphide, and gallium nitride, and where in the shield layer is between about 0.5 and 5 microns thick. The ground via and signal via may be formed by etching a blind hole in the front side of the first substrate, plating a conductive material into the blind hole, and grinding the obverse side of the substrate to expose the conductive material and form the through substrate via.

The method may further comprise forming a device on a second substrate, coupling the device electrically to the signal via and the ground via, and enclosing the device in a hermetic device cavity defined by the first and second substrates. The shield layer may comprise a metal layer that covers a majority of an inner surface of the device cavity. The method may further comprise forming a plurality of through substrate vias on the second substrate, forming a second metallic shield layer on the second substrate, and electrically coupling the second metallic shield layer to at least one of the plurality of through substrate vias. The method may further comprise disposing at least one solder ball on at least one of the first and the second substrate, wherein the at least one solder ball comprises at least one of SAC405 and AuSn, and coupling the first substrate to the second substrate with solder of the solder ball.

The method may further comprise forming at least one signal via and one ground via though a third substrate, forming a metallic shield layer over the third substrate which is configured to block RF radiation, electrically coupling the ground via to the metallic shield layer on the third substrate, and coupling the metallic shield layer on the third substrate to the metallic shield layer on the first substrate.

The method may be used to make an interconnect for an RF signal handling device. The interconnect may include at least one signal via and one ground via formed though a first substrate, a shield layer formed over the first substrate wherein the shield layer is configured to block RF radiation, wherein the the ground via is electrically coupled to the shield layer. The interconnect for an RF signal handling device may further comprise a thermal oxide which covers the surfaces of the substrate and walls of the ground via and signal via, and wherein the shield layer is between about 0.5 and 5 microns thick. The interconnect may further comprise a device formed on a second substrate, and a hermetic device cavity defined by the first and second substrates, which encloses the device formed on the second substrate. The metallic shield layer may cover a majority of an inner surface of the device cavity.

The interconnect for an RF signal handling device may further comprise at least one solder bump formed on at least one of the first and the second substrate, and wherein solder of the solder bump couples the first substrate to the second substrate. The interconnect for an RF signal handling device may further comprise at least one signal via and one ground via formed through a third substrate, a metallic shield layer formed over the third substrate which is configured to block RF radiation, wherein the ground via is electrically coupled to the metallic shield layer on the third substrate and the metallic shield layer on the third substrate is electrically coupled to the metallic shield layer on the first substrate.

Accordingly, an interconnect structure using a plurality of semiconductor substrates may be formed. The interconnect may comprise a first and a second substrate, each having one side coated with a highly conductive, unpatterned metal to form a shielding layer, an obverse side of each of the first and second substrate having a highly conductive metal patterned, to form RF transmission lines, a plurality of copper through substrate vias, that couple electrically the metal on the first surface to the metal on the obverse surface, and a plurality of solder bumps which couple the first substrate to the second substrate to for an RF transmission line structure.

The interconnect structure may further comprise a third substrate fabricated like the first substrate and second substrate, and coupled to the first and second substrates by a plurality of solder bumps. The interconnect may further comprise semiconductor devices electrically attached to at least one of the patterned and the unpatterned metal, and wherein the patterned and unpatterned metals are configured as co-planar waveguides that transmit signals to or from the semiconductor device. The interconnect may further comprise passive devices electrically coupled to at least one of the patterned and unpatterned metals.

Also disclosed here is a structure for routing RF signals in 3 dimensions, comprising a ground and a signal through wafer via formed in a first semiconductor wafer, a ground and a signal trace that connect the ground and a signal through wafer via on one or both surfaces of the first semiconductor wafer, a ground and signal via in a second semiconductor wafer, a ground and a signal trace that connects the vias on one or both surfaces of the second wafer, wherein ground traces and the signal traces on the second wafer are electrically coupled to the ground traces and the signal traces on the second wafer interconnections between the first and second wafers, when the first wafer is bonded to the second wafer.

The structure for routing RF signals in 3 dimensions may further include a third and fourth wafer, each of the third and fourth wafer also including a ground and a signal trace, and wherein the ground traces and the signal traces on the third and fourth wafers are electrically coupled to the ground traces and the signal traces on the first and second wafers, when the first wafer and second wafers are bonded to the third and fourth wafers.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Accordingly, the exemplary implementations set forth above, are intended to be illustrative, not limiting.

What is claimed is:

1. A method for forming a transmission line, comprising:
forming at least one signal via and one ground via though a first substrate;
forming a shield layer over the substrate which is configured to block RF radiation;
and coupling the ground via to the shield layer.

2. The method of claim 1, wherein the shield layer comprises at least one of gold (Au), silver (Ag) copper (Cu) or aluminum (Al), and the substrate is a semiconductor substrate comprising at least one of silicon, germanium, gallium arsenide, gallium phosphide, and gallium nitride, and where in the shield layer is between about 0.5 and 5 microns thick.

3. The method of claim 1, wherein the ground via and signal via are formed by:
etching a blind hole in the front side of the first substrate;
plating a conductive material into the blind hole; and
grinding the obverse side of the substrate to expose the conductive material and form the through substrate via.

4. The method of claim 1, further comprising:
forming a device on a second substrate;
coupling the device electrically to the signal via and the ground via; and
enclosing the device in a hermetic device cavity defined by the first and second substrates.

5. The method of claim 5, wherein the shield layer comprises a metal layer that covers a majority of an inner surface of the device cavity.

6. The method of claim 5, further comprising:
forming a plurality of through substrate vias on the second substrate;
forming a second metallic shield layer on the second substrate; and
electrically coupling the second metallic shield layer to at least one of the plurality of through substrate vias.

7. The method of claim 1, further comprising:
disposing at least one solder ball on at least one of the first and the second substrate, wherein the at least one solder ball comprises at least one of SAC405 and AuSn; and
coupling the first substrate to the second substrate with solder of the solder ball.

8. The method of claim 1, further comprising:
forming at least one signal via and one ground via though a third substrate;
forming a metallic shield layer over the third substrate which is configured to block RF radiation;
electrically coupling the ground via to the metallic shield layer on the third substrate; and coupling the metallic shield layer on the third substrate to the metallic shield layer on the first substrate.

9. An interconnect for an RF signal handling device, comprising:
at least one signal via and one ground via formed though a first substrate;
a shield layer formed over the first substrate wherein the shield layer is configured to block RF radiation, where in the
the ground via is electrically coupled to the shield layer.

10. The interconnect for an RF signal handling device of claim 10, further comprising:
a thermal oxide which covers the surfaces of the substrate and walls of the ground via and signal via, and wherein the shield layer is between about 0.5 and 5 microns thick.

11. The interconnect for an RF signal handling device of claim 10, further comprising:
a device formed on a second substrate; and
a hermetic device cavity defined by the first and second substrates, which encloses the device formed on the second substrate.

12. The interconnect for an RF signal handling device of claim 10, wherein the metallic shield layer covers a majority of an inner surface of the device cavity.

13. The interconnect for an RF signal handling device of claim 10, further comprising:
at least one solder bump formed on at least one of the first and the second substrate; and wherein
solder of the solder bump couples the first substrate to the second substrate.

14. The interconnect for an RF signal handling device of claim 11, further comprising:
at least one signal via and one ground via formed through a third substrate;
a metallic shield layer formed over the third substrate which is configured to block RF radiation, wherein
the ground via is electrically coupled to the metallic shield layer on the third substrate and the metallic shield layer on the third substrate is electrically coupled to the metallic shield layer on the first substrate.

15. An interconnect structure using a plurality of semiconductor substrates, comprising;
a first and a second substrate, each having one side coated with a highly conductive, unpatterned metal to form a shielding layer,
an obverse side of each of the first and second substrate having a highly conductive metal patterned, to form RF transmission lines;
a plurality of copper through substrate vias, that couple electrically the metal on the first surface to the metal on the obverse surface, and
a plurality of solder bumps which couple the first substrate to the second substrate to for an RF transmission line structure.

16. The interconnect structure of claim 18, further comprising:
a third substrate fabricated like the first substrate and second substrate, and coupled to the first and second substrates by a plurality of solder bumps.

17. The interconnect structure of claim 19, further comprising semiconductor devices electrically attached to at least one of the patterned and the unpatterned metal, and wherein the patterned and unpatterned metals are configured as co-planar waveguides that transmit signals to or from the semiconductor device,

18. The printed circuit structure of claim 19, further comprising passive devices electrically coupled to at least one of the patterned and unpatterned metals.

19. A structure for routing RF signals in 3 dimensions, comprising:
a ground and a signal through wafer via formed in a first semiconductor wafer;
a ground and a signal trace that connect the ground and a signal through wafer via on one or both surfaces of the first semiconductor wafer;
a ground and signal via in a second semiconductor wafer;
a ground and a signal trace that connects the vias on one or both surfaces of the second wafer;
wherein ground traces and the signal traces on the second wafer are electrically coupled to the ground traces and the signal traces on the second wafer interconnections between the first and second wafers, when the first wafer is bonded to the second wafer.

20. The structure for routing RF signals in 3 dimensions of claim 19, further comprising a third and fourth wafer, each of the third and fourth wafer also including a ground and a signal trace, and wherein the ground traces and the signal traces on the third and fourth wafers are electrically coupled to the ground traces and the signal traces on the first and second wafers, when the first wafer and second wafers are bonded to the third and fourth wafers.
